(19) United States
(12) Patent Application Publication
(10) Pub. No.: US 2013/0171824 A1
(43) Pub. Date: Jul. 4, 2013

(54) PROCESS FOR CHEMICALLY MECHANICALLY POLISHING SUBSTRATES CONTAINING SILICON OXIDE DIELECTRIC FILMS AND POLYSILICON AND/OR SILICON NITRIDE FILMS

(71) Applicants: Yuzhuo Li, Heidelberg (DE); Shyam Sundar Venkataraman, Zhongli City (TW); Harvey Wayne Pinder, Chicago, IL (US)

(72) Inventors: Yuzhuo Li, Heidelberg (DE); Shyam Sundar Venkataraman, Zhongli City (TW); Harvey Wayne Pinder, Chicago, IL (US)

(73) Assignee: BASF SE, Ludwigshafen (DE)

(21) Appl. No.: 13/821,769

(22) PCT Filed: Sep. 6, 2011
(86) PCT No.: PCT/IB2011/053893

§ 371 Date: Mar. 8, 2013

Related U.S. Application Data
(60) Provisional application No. 61/380,724, filed on Sep. 8, 2010.

(51) Int. Cl. H01L 21/306

(52) U.S. Cl. CPC H01L 21/30625
USPC 438/693

(57) ABSTRACT

CMP process for substrates containing silicon oxide dielectric films and polysilicon and/or silicon nitride films comprising the steps of (1) contacting the substrate with an aqueous composition containing (A) abrasive particles which are positively charged when dispersed in an aqueous medium having a pH in the range of from 3 to 9; (B) a water-soluble or water-dispersible linear or branched alkylene oxide homopolymer or copolymer; and (C) a water-soluble or water-dispersible polymer selected from (c1) aliphatic and cycloaliphatic poly(N-vinylamide) homopolymers and copolymers, (c2) homopolymers and copolymers of acrylamide monomers of the general formulas I and II: H₂C═C(—R)—C(=0)-N(—R¹)(—R²) (I), H₂C═C(—R)—C(=0)-R³ (II), wherein the variables have the following meaning R hydrogen atom, fluorine atom, chlorine atom, nitrile group, or organic residue; R¹ and R² hydrogen atom or organic residue; R³ saturated N-heterocyclic ring; (c3) cationic polymeric flocculants; and (c4) mixtures thereof; (2) polishing the substrate until the silicon oxide dielectric film is removed and the polysilicon and/or silicon nitride film is or are exposed exposed.

The present invention is directed to a novel process for polishing substrates for manufacturing electrical, mechanical and optical devices, the said substrates containing silicon oxide dielectric films and polysilicon and/or silicon nitride films.

### CITED DOCUMENTS

The documents cited in the present application are incorporated by reference in their entirety.

### BACKGROUND OF THE INVENTION

Chemical mechanical planarization or polishing (CMP) is the primary process to achieve local and global planarity of integrated circuits (ICs) devices. The technique typically applies CMP compositions or slurries containing abrasives and other additives as an active chemistry between a rotating substrate surface and a polishing pad under an applied load. Thus, the CMP process couples a physical process such as abrasion with a chemical process such as oxidation or chelation. It is not desirable for the removal or polishing of substrates to be comprised of purely physical or purely chemical action, but rather the synergistic combination of both in order to achieve a fast uniform removal.

This way, the substrate is removed until the desired planarity is achieved or a barrier sublayer or stopping layer is exposed. Ultimately, a planar, defect-free surface is obtained which enables proper multilayer IC device fabrication by subsequent photolithography, patterning, etching and thin-film processing.

Shallow trench isolation (STI) is a specific CMP application which generally requires the selective removal of silicon dioxide to silicon nitride on a patterned wafer substrate. In this case, etched trenches are overfilled with a dielectric material, e.g., silicon dioxide, which is polished using the silicon nitride barrier film as the stopping layer. The CMP process ends with clearing the silicon dioxide from the barrier film while minimizing the removal of exposed silicon nitride and trench silicon oxide.

This requires CMP slurries capable of achieving a high relative ratio of silicon dioxide material removal rate MRR to silicon nitride removal rate MRR which ratio is also referred to in the art as oxide-to-nitride selectivity.

Recently, polysilicon films are also used as barrier films or as an electrode material (cf. the U.S. Pat. No. 6,626,968 B2). Therefore, it has become highly desirable to have CMP slurries and methods available which allow for the global planarization of substrates containing silicon oxide dielectric and polysilicon films. This requires CMP slurries exhibiting a high oxide-to-polysilicon selectivity.

It is even more desirable to have CMP slurries and methods available which allow for the global planarization of substrates additionally containing silicon nitride films.

In this case, the oxide-to-nitride selectivity should not be too high, in order to avoid dishing, and other damages and defects in the globally planarized, heterogeneous, patterned surface containing silicon oxide, silicon nitride and polysilicon areas. However, the silicon nitride-to-polysilicon selectivity should also be high.

Ceria-based CMP slurries have received considerable attention in STI applications because of their ability to achieve a comparatively high oxide-to-nitride selectivity due to the high chemical affinity of ceria to silicon dioxide which is also referred to in the art as the chemical tooth action of ceria.

Nevertheless, the oxide-to-polysilicon selectivity of ceria-based CMP slurries must be improved by additives which “tailor” the selectivity.

Numerous attempts have been made to tailor the selectivity of ceria-based CMP slurries.

Thus, Jae-Don Lee et al. disclose in Journal of the Electrochemical Society, 149 (8), G477-G481, 2002, the effects of nonionic surfactants with different hydrophile-lipophile-balance (H LB) values such as polyethyleneoxides, ethyleneoxide-propyleneoxide copolymers and ethyleneoxide-propyleneoxide-ethyleneoxide triblock copolymers on oxide-to-polysilicon selectivity during CMP. However, fumed silica is used as the abrasive.

P. W. Carter et al. disclose in Electrochemical and Solid-State Letters, 8 (8) G218-G221 (2005), Interfacial Reactivity between Ceria and Silicon Dioxide and Silicon Nitride Surfaces, Organic Additive Effects, the influence of glutamic acid, picolinic acid, 4-hydroxybenzoic acid, imidazole, acetic acid, formic acid, 3-hydroxypicolinic acid, anthranilic acid, pyrrole carboxylic acid, cyclohexane carboxylic acid, piperazine, pyridine, 2-phenylacetic acid, benzoic acid, 3-aminophenol, succinic acid, betain, glycine, proline, benzenesulfonic acid, morpholine, salicylic acid, terephthalic acid, malic acid, isopropanol, citric acid and oxalic acid on the oxide-to-nitride selectivity.

Y. N. Prasad et al. disclose in Electrochemical and Solid-State Letters, 9 (12) G337-G339 (2006), Role of Amino-Acid Absorption on Silica and Silicon Nitride Surfaces during STI CMP, the influence of proline and arginine.

Hyun-Goo Kang et al. disclose in Journal of Material Research, volume 22, No. 3, 2007, pages 777 to 787, the effects of abrasive particles size and molecular weight of poly(acrylic acid) in ceria slurry on removal selectivity of SiO₂/Si₃N₄ films in shallow trench isolation chemical mechanical planarization.

S. Kim et al. disclose in Journal of Colloid and Interface Science, 319 (2008), pages 48 to 52, the absorption behavior of anionic polyelectrolyte for chemical mechanical polishing (CMP).

S. V. Babu et al., Electrochemical and Solid-State Letters, 7 (12) G327-G330 (2004), Slurry Additive Effects on the Suppression of Silicon Nitride Removal during CMP, investigated the influence of arginine, lysine, proline, N-methylglycine, alanine, glycine, picolinic acid, N,N-dimethylglycine, 3-aminobutyric acid and isonicotinic acid.

Jae-Dong Lee et al. disclose in Journal of the Electrochemical Society, 149 (8) G477-G481, 2002, Effects of Nonionic Surfactants on Oxide-To-Polysilicon Selectivity during Chemical Mechanical Polishing, the influence of surfactants such as polyethylene oxide (PEO) and ethyleneoxide-propyleneoxide-ethyleneoxide triblock copolymers on the selectivity. However, the oxide-to-nitride selectivity is not addressed.

The U.S. Pat. No. 5,738,800, U.S. Pat. No. 6,042,741, U.S. Pat. No. 6,132,637 and U.S. Pat. No. 6,218,305 B disclose a ceria-based CMP slurry containing complexing agents such as malic acid, tartaric acid, gluconic acid, citric acid, ortho di- and polyhydroxybenzoic acids, phthalic acid, pyrocathechol, pyrogallol, gallic acid, tannic acid and their salts. Moreover, the ceria-based CMP slurry contains an anionic, cationic, amphoteric or nonionic surfactant The ceria-based CMP slurry is claimed to have a high oxide-to-nitride selectivity.

The U.S. Pat. No. 5,759,917, U.S. Pat. No. 6,689,692 B1 and U.S. Pat. No. 6,984,588 B2 disclose a ceria-based CMP slurry containing a carboxylic acid such as acetic acid, adipic acid, butyric acid, capric acid, caproic acid, caprylic acid, citric acid, glutaric acid, glycolic acid, formic acid, fumaric acid, lactic acid, lauric acid, malic acid, maleic acid, malonic acid, myristic acid, oxalic acid, palmitic acid, phthalic acid, propionic acid, pyruvic acid, stearic acid, succinic acid, tartaric acid, valeric acid, 2-(2-methoxyethoxy) acetic acid, 2-[2-(2-methoxyethoxy)ethoxy]acetic acid, poly(ethylene glycol)bis(carboxymethyl)ether and their derivatives and salts. In addition, the ceria-based CMP slurry contains water-soluble organic and inorganic salts such as nitrates, phosphates and sulfates. The ceria-based CMP slurry is claimed to polish a silicon oxide overfill in preference to a silicon nitride layer.

The U.S. Pat. No. 6,299,659 B1 discloses a ceria-based CMP slurry wherein the abrasive particles have been treated with a silane, titanate, circonate, aluminum and phosphate coupling agent in order to improve the oxide-to-nitride selectivity.

The American patent application US 2002/0034875 A1 and the U.S. Pat. No. 6,626,968 B2 disclose a ceria-based CMP slurry containing surfactants, pH adjusting agents such as potassium hydroxide, sulfuric acid, nitric acid, hydrochloric acid or phosphoric acid, and polymers containing a hydrophilic functional group and a hydrophobic functional group such as polyvinyl methyl ether (PVME), polyethylene glycol (PEG), polyoxyethylene 23 lauryl ether (POLE), polypropanoic acid (PPA), polyacrylic acid (PM), and polyether glycol bis ether (PEGBE). The ceria-based CMP slurry increases the oxide-to-polysilicon selectivity.

The U.S. Pat. No. 6,436,835 B1 discloses a ceria-based CMP slurry for the shallow trench isolation process comprising water-soluble organic compounds having carboxylic acid or carboxylate or sulfonic acid or sulfamic groups such as polyacrylic acid, polymethacrylic acid, naphthalene sulfonic acid-formalin condensate, malic acid, lactic acid, tartaric acid, gluconic acid, citric acid, succinic acid, adipic acid, fumaric acid, aspartic acid, glutamic acid, glycine 4-aminobutyric acid, 6-aminohexanoic acid, 12-aminolauric acid, arginine, glycylglycine, laurylbenzene sulfonic acid and their ammonium salts. The ceria-based CMP slurry is claimed to have a high oxide-to-nitride selectivity.

The U.S. Pat. No. 6,491,843 B1, U.S. Pat. No. 6,544,892 B2 and U.S. Pat. No. 6,627,107 B2 disclose a ceria-based CMP slurry containing alpha-amino acids such as lysine, alanine, and proline for improving the oxide-to-nitride selectivity.

The U.S. Pat. No. 6,616,514 B1 discloses a ceria-based CMP slurry containing organic polyols having at least 3 hydroxyl groups that are not dissociable in the aqueous medium; or a polymer formed from at least one monomer having at least 3 hydroxyl groups that are not dissociable in the aqueous medium such as mannitol, sorbitol, mannose, xylitol, sorbose, sucrose, and dextrin for improving the oxide-to-nitride selectivity.

The U.S. Pat. No. 7,071,105 B2 and the American application US 2006/0144824 A1 disclose a ceria-based CMP slurry containing a polishing additive comprising functional groups having a pKa of 4 to 9. The polishing additive is selected from the group consisting of arylamines, aminoalcohols, aliphatic amines, heterocyclic amines, hydroxamic acids, aminocarboxylic acids, cyclic monocarboxylic acids, unsaturated monocarboxylic acids, substituted phenols, sulfonamides, thiols and salts thereof, in particular, chlorides, bromides, sulfates, sulfonates, trifluoromethyl sulfonates, acetates, trifluoroacetates, picrates, perfluorobutyrates as well as sodium, potassium and ammonium salts.

The arylamines expressly mentioned are aniline, 4-chloroaniline, 3-methoxyaniline, N-methylaniline, 4-methoxyaniline, p-toluidine, anthranilic acid, 3-amino-4-hydroxybenzenesulfonic acid, aminobenzylalcohol, aminobenzylamine, 1-(-aminophenyl)pyrrole, 1-(3-aminophenyl)ethanol, 2-aminophenyl ether, 2,5-bis-(4-aminophenyl)-1,3,4-oxidadiazole, 2-(2-aminophenyl)-1H-1,3,4-triazole, 2-aminophenyl, 3-aminophenyl, 4-aminophenyl, dimethylaminophenol, 2-aminothiolphenol, 3-aminothiolphenol, 4-aminophenyl methyl sulfide, 2-aminobenzenesulfonamide, orthanilic acid, 3-aminobenzene boronic acid, 5-aminoisophthalic acid, sulfacetamide, sulfanilic acid, o- or p-arsanilic acid, and (3R)-3-(4-trifluoromethylphenylamino) pentanoic acid.

The aminoalcohols expressly mentioned are triethanolamine, benzyldiethanolamine, tris(hydroxylmethyl)aminomethane, hydroxylamine, and tetracycline.

The aliphatic amines expressly mentioned are methoxyamine, hydroxylamine, N-methylhydroxylamine, N,O-dimethylhydroxylamine, beta-difluoroethylamine, ethylenediamine, triethylenediamine, diethyl((butylamino)(2-hydroxyphenyl)methyl)phosphonate, iminoethanes, iminobutanes, triallylamine, cyanoamines such as aminoacetonitrile, dimethylaminoacetonitrile, 2-amino-2-cyanopropane, isopropylaminopropionitrile, diethylaminopropionitrile, aminopropionitrile, dicyanodiethylamine), hydrazine, methylhydrazine, tetramethylhydrazine, N,N-dimethylhydrazine, phenylhydrazine, N,N-diethylhydrazine, trimethylhydrazine, ethylhydrazine and salts thereof.

The heterocyclic amines expressly mentioned are imidazole, 1-methylimidazole, 2-methylimidazole, 2-ethylimidazole, 2-hydroxylmethylimidazole, 1-methyl-2-hydroxylmethylimidazole, benzoimidazole, quinoline, isoquinoline, hydroxyquinoline, melamine, pyridine, bipyridine, 2-methylpyridine, 4-methylpyridine, 2-aminopyridine, 3-aminopyridine, 2,3-pyridinedicarboxylic acid, 2,5-pyridinedicarboxylic acid, 2,6-pyridinedicarboxylic acid, 5-butyl-2-pyridinecarboxylic acid, 2-pyridinecarboxylic acid, 3-hydroxy-2-pyridinecarboxylic acid, 4-hydroxy-2-pyridinecarboxylic acid, 3-benzoyl-2-pyridinecarboxylic acid, 6-methyl-2-pyridinecarboxylic acid, 3-methyl-2-pyridinecarboxylic acid, 6-bromo-2-pyridinecarboxylic acid, 6-chloro-2-pyridinecarboxylic acid, 3,6-dichloro-2-pyridinecarboxylic acid, 4-hydrazino-3,5,6-trichloro-2-pyridinecarboxylic acid, 2-quinolinecarboxylic acid, 4-methoxy-2-quinolinecarboxylic acid, 8-hydroxy-2-quinolinecarboxylic acid, 4,8-hydroxy-2-quinolinecarboxylic acid, 7-chloro-4-hydroxy-2-quinolinecarboxylic acid, 5,7-dichloro-4-hydroxy-2-quinolinecarboxylic acid, 5-nitro-2-quinolinecarboxylic acid, 1-isoquinolinecarboxylic acid, 3-isoquinolinecarboxylic acid, acridine, benzoquinoline, benzacridine, clonidine, anabasine, nornicotine, triazolopyridine, pyridoxine, serotonin, histamine, benzodiazepine, aziridine, morpholine, 1,8-diazabicyclo(5,4,0)undecene-7 DABCO, hexamethylenetetramine, piperazine, N-benzoylpiperazine, 1-tosylpiperazine, N-carboxyethylpiperazine, 1,2,3-triazole, 1,2,4-triazole, 2-aminothiazole, pyrrole, pyrrole-2-carboxylic acid, 3-pyrroline-2-carboxylic acid, ethylpyrroline, cyclohexylpyrroline, tolylpyrroline, tetrazole, 5-cyclopropyltetrazole, 5-hydroxytetrazole, 5-phenoxytetrazole, 5-phenyltetrazole, fluorouracil, methylthiouracil, 5,5-diphenylhydantoin, 5,5-dimethyl-2,4-oxazolidinedione, phthalimide, succinimide, 3,3-methylphenylglutarimide, 3,3-dimethylsuccinimide, imidazol[2,3-b]thioxazole, hydroxyemidazo[2,3-a]isoindole, 5,5-methylphenylbarbituric acid, 1,5,5-trimethylbarbituric acid, hexobarbital, 5,5-dimethylbarbituric acid, 1,5-dimethyl-5-phenylbarbituric acid and their salts.

The hydroxamic acids specifically mentioned are formohydroxamic acid, acetohydroxamic acid, benzohydroxamic acid, salicylhydroxamic acid, 2-aminobenzohydroxamic acid, 2-chlorobenzohydroxamic acid, 2-fluorobenzohydroxamic acid, 2-nitrobenzohydroxamic acid, 3-nitrobenzohydroxamic acid, 4-aminobenzohydroxamic acid, 4-chlorobenzohydroxamic acid, 4-fluorobenzohydroxamic acid, 4-nitrobenzohydroxamic acid and their salts.

The aminocarboxylic acids expressly mentioned are glutamic acid, beta-hydroxyglutamic acid, aspartic acid, asparagine, azaserine, cysteine, histidine, 3-methylhistidine, cytosine, 7-aminocephalosporanic acid and carnosine.

The cyclic monocarboxylic acids expressly mentioned are naphthalene-2-carboxylic acid, cyclohexane carboxylic acid, cyclohexyl acetic acid, 2-phenyllactic acid, 4-hydroxybenzoic acid, 3-hydroxybenzoic acid, 2-pyridinecarboxylic acid, cis- and trans-, cyclohexane carboxylic acid, benzoic acid eyes and salts thereof.

The unsaturated monocarboxylic acids expressly mentioned are cinnamic acid, acrylic acid, 3-chloroprop-2-enecarboxylic acid, crotonic acid, 4-but-2-enecarboxylic acid, cis- or trans-2-pentanoic acid, 2-methyl-2-pentanoic acid, 2-hexenoic acid and 3-ethyl-2-hexenoic acid and their salts.

The phenols expressly mentioned are nitrophenol, 2,6-dihalo-4-nitrophenols, 2,6-di-C₁₋₁₂-alkyl-4-nitrophenols, 2,4-dinitrophenol, 3,4-dinitrophenol, 2-C₁—12-alkyl-4,6-dinitrophenols, 2-halo-4,6-dinitrophenols, dinitro-o-cresol, picric acid and salts thereof.

The sulfonamides expressly mentioned are N-chlorotolylsulfonamide, dichlorophenamide mafenide, nimesulide, sulfamethizole, sulfaperin, sulfacetamide, sulfadiazine, sulfadimethoxine, sulfamethazine, sulfapyridine, sulfaquinoxaline and their salts.

The thiols expressly mentioned are hydrogen disulfide, cysteamine, cysteinylcysteine, methyl cysteine, thiophenol, p-chloro thiophenol, o-aminothiolphenol, o-mercaptophenyl acetic acid p-nitrobenzenethiol, 2-mercaptoethanesulfonate, N-dimethylcysteamine, dipropylcysteamine, diethylcysteamine, mercaptoethylmorpholine, methylthioglycolate, mercaptoethylamine, N-trimethylcysteine, glutathione, mercaptoethylpiperidine, diethylaminopropanethiol and their salts.

The polishing additives are believed to increase the oxide-to-nitride selectivity.

The American patent application US 2006/0124594 A1 discloses a ceria-based CMP slurry having a viscosity of at least 1.5 cP and comprising a viscosity increasing agent including a non-ionic polymer such as polyethylene glycol (PEG). The ceria-based CMP slurry is said to have a high oxide-to-nitride selectivity and a low within-wafer non-uniformity WIWNU.

The American patent application US 2006/0207188 A1 discloses a ceria-based CMP slurry containing the reaction product of a polymer such as polyacrylic acid or poly(alkyl methacrylate) and a monomer such as acrylamide, methacrylamide, ethyl-methacrylamide, vinylpyridine, or vinylpyrrolidone. The reaction products are believed to increase also the oxide-to-nitride selectivity.

The American patent application US 2006/0216935 A1 discloses a ceria-based CMP slurry comprising protein, lysine and/or arginine and a pyrrolidone compounds such as polyvinylpyrrolidone (PVP), N-octyl-2-pyrrolidone, N-ethyl-2-pyrrolidone, N-hydroxyethyl-2-pyrrolidone, N-cyclohexyl-2-pyrrolidone, N-butyl-2-pyrrolidone, N-hexyl-2-pyrrolidone, N-decyl-2-pyrrolidone, N-octadecyl-2-pyrrolidone, and N-hexadecyl-2-pyrrolidone. The ceria-based CMP slurry can furthermore contain dispersing agents like polyacrylic acid, glycols and polyglycols. Specific examples use proline, polyvinylpyrrolidone or N-octyl-2-pyrrolidone, PPO/PEO blockcopolymers, and glutaraldehyde. The ceria-based CMP slurry is believed to not aggressively remove trench silicon dioxide thereby allowing for extended polishing beyond the endpoint without substantially increasing the minimum step height.

The American patent application US 2007/0077865 A1 discloses a ceria-based CMP slurry containing polyethyleneoxides/polypropyleneoxide copolymers preferably from the Pluronic™ family sold by BASF. The ceria-based CMP slurry can furthermore contain amino alcohols such as 2-dimethylamino-2-methyl-1-propanol (DMAMP), 2-amino-2-ethyl-1-p ropa no I (A M P), 2-(2-aminoethylamino)ethanol, 2-(isopropylamino)ethanol, 2-(methylamino)ethanol, 2-(diethylamino)ethanol, 2-(2-dimethylamino)ethoxy)ethanol, 1,1′-[[3-(dimethylamino)propyl]imino]-bis-2-propanol, 2-(2-butylamino)ethanol, 2-(tert-butylamino)ethanol, 2-(diisopropylamino)ethanol, and N-(3-aminopropyl)morpholine. The ceria-based CMP slurry may furthermore contain quaternary ammonium compounds like tetramethylammonium hydroxide, film forming agents such as alkyl amines, alkanolamines, hydroxylamines, phosphate esters, sodium lauryl sulfate, fatty acids, polyacrylates, polymethacrylates, polyvinylphosphonates, polymalates, polystyrene sulfonate, polyvinyl sulfate, benzotriazole, triazole, and benzoimidazole, and complexing agents such as acetylacetone, acetates, glycolates, lactates, gluconates, gallic acid, oxalates, phthalates, citrates, succinates, tartates, malates, ethylenediaminetetraacetic acid, ethylene glycol, pyrocatechol, pyrogallol, tannic acid, phosphonium salts and phosphonic acids. The ceria-based CMP slurry is believed to provide good selectivity of silicon oxide and/or silicon nitride relative to polysilicon.

The American patent application US 2007/0175104 A1 discloses a ceria-based CMP slurry comprising a polysilicon polishing inhibitor which is selected from water-soluble polymers having a N-monosubstituted or N,N-di-substituted skeleton substituted by any members selected from the group consisting of acrylamide, methacrylamide and alpha-substituted derivatives thereof; polyethylene glycols; polyvinylpyrrolidones; alkyloxylated linear aliphatic alcohols and ethyleneoxide adducts of acetylene-based diols. The ceria-based CMP slurry may contain additional water-soluble polymers such as polysaccharides like alginic acid, pectin acid, carboxymethylcellulose, agar, curdlan, and pullulan; polycarboxylic acids such as polyaspartic acid, polyglutamic acid, polylysine, polymalic acid, polymethacrylic acid, polyimide acid, polymaleic acid, polyitaconic acid, polyfumaric acid, poly(p-styrene carboxylic acid), polyacrylic acid, polyacrylamide, amino polyacrylamide, polyglyoxalic acid and their salts; and vinyl polymers such as polyvinyl alcohol, and polyacrolein. The ceria-based CMP slurry is said to have a high silicon oxide over polysilicon selectivity.

The American patent application US 2007/0191244 A1 discloses a ceria-based CMP slurry containing a compound having a weight-average molecular weight of 30 to 500 and containing hydroxyl groups and a carboxyl group or both such as citrates, malates, gluconates, tartrates, 2-hydroxyisobutyrates, adipates, octanoates, succinates, EDTA-containing compounds, glutarates, methylenesuccinates, mannose, glycero-galacto-heptose, erythro-manno-octose, arabino-galacto-nonose, and glutamine. The ceria-based CMP slurry may furthermore contain linear polymer acids or graft type polymer acids having alkoxypolyalkylene glycol side chains. The ceria-based CMP slurry is said to achieve an improved global planarity of the polished wafers.

The American patent application US 2007/0218811 A1 discloses a ceria-based CMP slurry having a pH of 4 to 7.5 and containing a dispersing agent, a polycarboxylic acid, and 100 to 1000 ppm of a strong acid having a pKa of its first dissociable acidic group at 3.2 or less. By way of examples, polymers of acrylic acid and methacrylic acid are mentioned as anionic dispersing agents, polyoxyethylene derivatives are mentioned as nonionic dispersing agents, and polyvinylpyrrolidone is mentioned as a cationic dispersing agent. Specifically mentioned strong acids are sulfuric acid, HCl, nitric acid, phosphoric acid, oxalic acid, maleic acid, picric acid, sulfurous acid, thiosulfurous acid, amidosulfuric acid, chloric acid, perchloric acid, chlorous acid, hydroiodic acid, periodic acid, iodic acid, hydrobromic acid, perbromic acid, chromic acid, nitrous acid, diphosphonic acid, tripolyphosphoric acid, phosphinic acid, picolinic acid, phosphonic acid, isonicotinic acid, nicotinic acid, trichloroacetic acid, dichloroacetic acid, chloroacetic acid, cyanoacetic acid, oxaloacetic acid, nitroacetic acid, bromoacetic acid, fluoroacetic acid, phenoxyacetic acid, o-bromobenzoic acid, o-nitrobenzoic acid, o-chlorobenzoic acid, p-aminobenzoic acid, anthranilic acid, phthalic acid, fumaric acid, malonic acid, tartaric acid, citric acid, o-chloroaniline, 2,2′-bipyridine, 4,4′-bipyridine, 2,6-pyridinedicarboxylic acid, pyruvic acid, polystyrene sulfonic acid, polysulfonic acid, glutamic acid, salicylic acid, aspartic acid, 2-aminoethylphosphonic acid, lysine, arginine, isoleucine, sarcosine, ornithine, guanosine, citrulline, tyrosine, valine, hypoxanthine, methionine, lysine, and leucine. The ceria-based CMP slurry is said to cause an efficient high-speed operation, an easier process management and a smaller fluctuation in film thickness due to difference in pattern density.

The American patent applications US 2008/0085602 A1 and US 2008/0124913 A1 disclose a ceria-based CMP slurry containing 0.001 to 0.1% by weight of the nonionic surfactant selected from ethyleneoxide-propyleneoxide-ethyleneoxide triblock copolymers and polyacrylic acid as dispersing agent. The ceria-based slurry he said to have a high silicon oxide and silicon nitride over polysilicon selectivity.

The fabrication of electrical devices, in particular, semiconductor integrated circuits (ICs); requires high precision methods which involve inter alia high selectivity CMP.

Although the prior art ceria-based CMP slurries may have a satisfactory oxide-to-polysilicon, oxide-to-nitride and nitride-to-polysilicon selectivities and may yield polished wafers having a good global and local planarity as exemplified by the within-wafer nonuniformity (WIWNU) and the wafer-to-wafer nonuniformity (WTWNU), the ever decreasing dimensions of the IC architectures, in particular ICs with LSI (large-scale integration) or VLSI (very-large-scale integration), necessitate the constant improvement of the ceria-based CMP slurries in order to and meet the ever increasing technical and economical demands of the manufacturers of integrated circuit devices.

However, this pressing need to constantly improve the prior art ceria-based CMP slurries does not only apply to the field of integrated circuit devices, but the polishing and planarization efficacy has also to be improved in the fields of manufacturing other electrical devices such as liquid crystal panels, organic electroluminescent panels, printed circuit boards, micro machines, DNA chips, micro plants, photovoltaic cells, and magnetic heads; as well as high precision mechanical devices and optical devices, in particular, optical glasses such as photo-masks, lenses and prisms, inorganic electro-conductive films such as indium tin oxide (ITO), optical integrated circuits, optical switching elements, optical waveguides, optical monocrystals such as the end faces of optical fibers and scintillators, solid laser monocrystals, sapphire substrates for blue laser LEDs, semiconductor monocrystals, and glass substrates for magnetic disks. The manufacturing of such electrical and optical devices also requires high precision CMP process steps.

### OBJECTS OF THE INVENTION

Therefore, it is an object of the present invention to provide a novel process for chemically mechanically polishing substrates, in particular semiconductor substrates, containing silicon oxide dielectric films and polysilicon and/or silicon nitride films, which process no longer exhibits the disadvantages and drawbacks of the prior art CMP processes.

In particular, the novel CMP process should exhibit a significantly improved oxide-to-polysilicon, oxide-to-nitride and nitride-to-polysilicon selectivity and yield polished wafers having an excellent global and local planarity as exemplified by the within-wafer nonuniformity (WIWNU) and the wafer-to-wafer nonuniformity (WTWNU). Therefore, they should be excellently suited for manufacturing IC architectures, in particular ICs with LSI (large-scale integration) or VLSI (very-large-scale integration), having structures with dimensions below 50 nm.

Moreover, the novel CMP process should not only be exceptionally useful in the field of integrated circuit devices, but should also be most efficiently and advantageously useful in the fields of manufacturing other electrical devices such as liquid crystal panels, organic electroluminescent panels, printed circuit boards, micro machines, DNA chips, micro plants and magnetic heads; as well as high precision mechanical devices and optical devices, in particular, optical glasses such as photo-masks, lenses and prisms, inorganic electro-conductive films such as indium tin oxide (ITO), optical integrated circuits, optical switching elements, optical waveguides, optical monocrystals such as the end faces of optical fibers and scintillators, solid laser monocrystals, sapphire substrates for blue laser LEDs, semiconductor monocrystals, and glass substrates for magnetic disks.

### SUMMARY OF THE INVENTION

Accordingly, the novel process for chemically mechanically polishing substrates and containing silicon oxide dielectric films and polysilicon and/or silicon nitride films has been found, the said process comprising the steps of
(1) contacting the substrate at least once with an aqueous polishing composition containing
   (A) at least one type of abrasive particles which are positively charged when dispersed in an aqueous medium having a pH in the range of from 3 to 9 as evidenced by the electrophoretic mobility;
   (B) at least one water-soluble or water-dispersible polymer selected from the group consisting of linear and branched alkylene oxide homopolymers and copolymers; and
   (C) at least one water-soluble or water-dispersible polymer selected from the group consisting of
      (c1) linear and branched, aliphatic and cycloaliphatic poly(N-vinylamide) homopolymers and copolymers,
      (c2) homopolymers and copolymers of acrylamide monomers of the general formulas I and II:

H₂C═C(—R)—C(═O)—N(—R¹)(—R²) (I),

H₂C═C(—R)—C(═O)—R³ (II),
wherein the variables have the following meaning
R hydrogen atom, fluorine atom, chlorine atom, nitrile group, residue comprising or consisting of at least one moiety selected from the group consisting of substituted and unsubstituted aliphatic moieties having 1 to 6 carbon atoms, substituted and unsubstituted cycloaliphatic moieties having 3 to 10 carbon atoms, and substituted and unsubstituted aromatic moieties having 6 to 10 carbon atoms;
R¹ and
R² the same or different from each other and independent of each other hydrogen atom or residue comprising or consisting of at least one moiety selected from the group consisting of substituted and unsubstituted aliphatic moieties having 1 to 20 carbon atoms, substituted and unsubstituted cycloaliphatic moieties having 3 to 10 carbon atoms, substituted and unsubstituted aromatic moieties having 6 to 10 carbon atoms;
R³ substituted or unsubstituted, saturated heterocyclic ring containing at least one nitrogen atom, the said heterocyclic ring being linked to the carbon atom of the carbonyl moiety via a covalent carbon nitrogen bond; the said homopolymers and copolymers having a weight average molecular weight of less than 100,000 Dalton;
(c3) cationic polymeric flocculants having a weight average molecular weight of less than 100,000 Dalton; and
(c4) mixtures thereof;
(2) polishing the substrate at a temperature and for the time sufficient to remove the silicon oxide dielectric film and expose the polysilicon and/or silicon nitride film; and
(3) removing the polished substrate from the contact with the aqueous polishing composition.

Hereinafter, the novel process for polishing substrates for mechanical, electrical and optical devices is referred to as the “process of the invention”.

### Advantages of the Invention

In view of the prior art, it was surprising and could not be expected by the skilled artisan that the objects of the present invention could be solved by the process of the invention.

It was particularly surprising that the process of the invention exhibited a significantly improved oxide-to-polysilicon, oxide-to-nitride and nitride-to-polysilicon selectivity and yielded polished wafers having an excellent global and local planarity as exemplified by the within-wafer nonuniformity (WIWNU) and the wafer-to-wafer nonuniformity (WTWNU). Therefore, they were excellently suited for manufacturing IC architectures, in particular ICs with LSI (large-scale integration) or VLSI (very-large-scale integration), having structures with dimensions below 50 nm.

Moreover, the process of the invention was not only exceptionally useful in the field of integrated circuit devices, but was also most efficiently and advantageously useful in the fields of manufacturing other electrical devices such as liquid crystal panels, organic electroluminescent panels, printed circuit boards, micro machines, DNA chips, micro plants and magnetic heads; as well as high precision mechanical devices and optical devices, in particular, optical glasses such as photo-masks, lenses and prisms, inorganic electro-conductive films such as indium tin oxide (ITO), optical integrated circuits, optical switching elements, optical waveguides, optical monocrystals such as the end faces of optical fibers and scintillators, solid laser monocrystals, sapphire substrates for blue laser LEDs, semiconductor monocrystals, and glass substrates for magnetic disks.

Most particularly however, the process of the invention was excellently suited for polishing semiconductor wafers containing silicon oxide dielectric and polysilicon films and optionally containing silicon nitride films. The process of the invention yielded polished wafers having an excellent global and local planarity and balance without dishing, cupping or hotspots as exemplified by the within-wafer nonuniformity (WIWNU) and the wafer-to-wafer nonuniformity (WTWNU). Therefore, they were excellently suited for manufacturing IC architectures, in particular ICs with LSI (large-scale integration) or VLSI (very-large-scale integration), having structures with dimensions below 50 nm.

### DETAILED DESCRIPTION OF THE INVENTION

The polishing composition used in the process of the invention is an aqueous composition. This means that it contains water, in particular ultrapure water, as the main solvent and dispersing agent. Nevertheless, the composition used in the process of the invention may contain at least one water-miscible organic solvent, however, only in minor amounts that do not change the aqueous nature of the polishing composition.

Preferably, the polishing composition contains water in amounts of from 60 to 99.95% by weight, more preferably 70 to 99.9% by weight, even more preferably 80 to 99.9% by weight and, most preferably, 90 to 99.9% by weight, the weight percentages being based on the complete weight of the polishing composition.

“Water-soluble” means that the relevant component or ingredient of the composition used in the process of the invention can be dissolved in the aqueous phase on the molecular level.

“Water-dispersible” means that the relevant component or ingredient of the composition used in the process of the invention can be dispersed in the aqueous phase and forms a stable emulsion or suspension.

The first essential ingredient of the polishing composition is at least one, preferably one, type of abrasive particles (A).

The abrasive particles (A) are positively charged when the dispersed in an aqueous medium which has a pH in the range of from 3 to 9. The positive charge is evidenced by the electrophoretic mobility μ (μm/s) (V/cm) of the abrasive particles (A). The electrophoretic mobility μ can be directly measured with instruments such as Zetasizer Nano from Malvern, Ltd.

The average particle size of the abrasive particles (A) can vary broadly and, therefore, can be adjusted most advantageously to the particular requirements of a given polishing composition and process of the invention. Preferably, the average particle size as determined by dynamic laser light scattering is in the range of from 1 to 2000 nm, preferably 1 to 1000 nm, more preferably 1 to 750, and, most preferably, 1 to 500 nm.

The particle size distribution of the abrasive particles (A) can be monomodal, bimodal or multimodal. Preferably, the particle size distribution is monomodal in order to have an easily reproducible property profile of the abrasive particles (A) and easily reproducible conditions during the process of the invention.

Moreover, the particle size distribution of the abrasive particles (A) can be narrow or broad. Preferably, the particle size distribution is narrow with only small amounts of small particles and large particles in order to have an easily reproducible property profile of the abrasive particles (A) and easily reproducible conditions during the process of the invention.

The abrasive particles (A) can have various shapes. Thus, they may be of one or essentially one type of shape. However, it also possible that the abrasive particles (A) have different shapes. In particular, two types of differently shaped abrasive particles (A) may be present in a given composition used in the process of the invention. As regards the shapes themselves, they can be cubes, cubes with chamfered edges, octahedrons, icosahedrons, nodules and spheres with or without protrusions or indentations. Most preferably, the shape is spherical with no or only very few protrusions or indentations. This shape, as a rule, is preferred because it usually increase is the resistance to the mechanical forces the abrasive particles (A) are exposed to it during a CMP process.

In principle, any type of abrasive particles (A) can be used in the composition used in the process of the invention as long as they possess the above described property profile. Thus, the abrasive particles (A) may be organic or inorganic particles or organic-inorganic hybrid particles. Preferably, the abrasive particles (A) are inorganic particles.

In principle, any type of inorganic abrasive particles (A) can be used in the composition used in the process of the invention as long as they possess the above described property profile. However, most preferably, inorganic abrasive particles (A) containing or consisting of ceria are used.

The abrasive particles (A) which contain ceria can contain minor amounts of other rare earth metal oxides.

Preferably, the abrasive particles (A) which contain ceria are composite particles (B) comprising a core containing or consisting of at least one other abrasive particulate material which is different from ceria, in particular alumina, silica, titania, zirconia, zinc oxide, and mixtures thereof.

Such composite particles (A) are known, for example, from WO 2005/035688 A1, U.S. Pat. No. 6,110,396, U.S. Pat. No. 6,238,469 B1, U.S. Pat. No. 6,645,265 B1, K. S. Choi et al., Mat. Res. Soc. Symp. Proc. Vol. 671, 2001 Materials Research Society, M5.8.1 to M5.8.10, S.-H. Lee et al., J. Mater. Res., Vol. 17, No. 10, (2002), pages 2744 to 2749, A. Jindal et al., Journal of the Electrochemical Society, 150 (5) G314-G318 (2003), Z. Lu, Journal of Materials Research, Vol. 18, No. 10, October 2003, Materials Research Society, or S. Hedge et al., Electrochemical and Solid-State Letters, 7 (12) G316-G318 (2004).

Most preferably, the composite particles (A) are raspberry-type coated particles comprising a core selected from the group consisting of alumina, silica titania, zirconia, zinc oxide, and mixtures thereof with a core size of from 20 to 100 nm wherein the core is coated with ceria particles having a particle size below 10 nm.

The amount of the abrasive particles (A) used in the polishing composition can vary broadly and, therefore, can be adjusted most advantageously to the particular requirements of a given polishing composition and process of the invention. Preferably, the polishing composition used in the process of the invention contains 0.005 to 10% by weight, more preferably 0.01 to 8% by weight and, most preferably 0.01 to 6% by weight of the abrasive particles (A), the weight percentages being based on the complete weight of the polishing composition.

The second essential ingredient of the polishing composition is at least one, preferably one, water-soluble or water-dispersible, preferably water-soluble, polymer (B) selected from the group consisting of linear and branched alkylene oxide, preferably ethyleneoxide and propyleneoxide, homopolymers and copolymers.

The preferred ethyleneoxide-propyleneoxide copolymers (B) can be random copolymers, alternating copolymers or blockcopolymers containing polyethyleneoxide blocks and polypropyleneoxide blocks.

Preferably, in the ethyleneoxide-propyleneoxide blockcopolymers, the polyethyleneoxide blocks have hydrophile-lipophile-balance (HLB) values from 10 to 15. The polypropyleneoxide blocks may have a HLB values of from 28 to about 32

The water-soluble or a water-dispersible polymers (B) are customary and known, commercially available materials. Suitable water-soluble polymers (B) are described in the Japanese patent application JP 2001-240850 A, claim 2 in conjunction with the paragraphs [0007] to [0014], the American patent application US 2007/0077865 A1, column page 1, paragraph [0008] to page 2, paragraph [0010], the American patent application US 2006/0124594 A1, page 3, paragraphs [0036] and [0037] and the American patent application US 2008/0124913 A1, page 3, paragraphs [0031] to [0033] in conjunction with the claim 14 or they are sold under the trademarks Pluronic™, Tetronic™ and Basensol™ by BASF Corporation and BASF SE as evidenced by the company brochure of BASF Corporation “Pluronic™ & Tetronic™ Block Copolymer Surfactants, 1996” or the American patent US 2006/0213780 A1.

Most preferably, polyethylene glycol (PEG) is used as the polymer (B).

The concentration of the water-soluble or water-dispersible polymer (B) in the polishing composition can vary broadly and, therefore, can be adjusted most advantageously to the particular requirements of a given composition and process of the invention. Preferably, the polishing composition contains the water-soluble polymer (B) in amounts of from 0.001 to 5% by weight, more preferably 0.005 to 2.5% by weight, even more preferably 0.0075 to 1% by weight and, most preferably, 0.0075 to 0.5% by weight, the weight percentages being based on the complete weight of the polishing composition.

The third essential ingredient of the polishing composition is at least one, preferably one, water-soluble or water-dispersible, preferably water-soluble, polymer (C) which is selected from the group consisting of the polymers (c1), (c2) and (c3) and mixtures thereof.

The polymers (c1) are linear and branched, aliphatic and cycloaliphatic poly(N-vinylamide) homopolymers and copolymers.

Preferably, the aliphatic and cycloaliphatic N-vinylamide monomers, which are the building blocks of the linear and branched, aliphatic and cycloaliphatic poly(N-vinylamide) homopolymers and copolymers (c1), are selected from the group consisting of N-vinylacetamide, N-vinylpyrrolidone, N-vinylvalerolactam, N-vinylcaprolactam, N-vinylsuccinimide and mixtures thereof. Most preferably, N-vinylpyrrolidone is used.

The poly(N-vinylamide) copolymers (c1) may contain monomeric units derived from customary and known olefinically unsaturated monomers other than the N-vinylamides, as for example, vinyl esters and ethers, acrylic and methacrylic esters, allylic esters and ethers, olefins which may be substituted by halogen atoms or nitrile groups, and styrenic monomers, provided that such monomeric units are only contained in such amounts that the water-solubility is not jeopardized.

Preferably, the water-soluble polymers (c1) have a weight average molecular weight of from 2000 to 1,000,000 Dalton, more preferably 5000 to 500,000 Dalton and, most preferably, 10,000 to 250,000 Dalton.

The polymers (c2) are homopolymers and copolymers of acrylamide monomers of the general formulas I and/or II:

H₂C═C(—R)—C(═O)—N(—R¹)(—R²) (I),

H₂C═C(—R)—C(═O)—R³ (II).

In the general formulas I and II, R represents a hydrogen atom, a fluorine atom, a chlorine atom, a nitrile group or residue comprising or consisting at least one, preferably one, moiety selected from the group consisting of substituted and unsubstituted aliphatic moieties having 1 to 6 carbon atoms, substituted and unsubstituted cycloaliphatic moieties having 3 to 10 carbon atoms, substituted and unsubstituted aromatic moieties having 6 to 10 carbon atoms.

Here and hereinafter any substituent can be used as long as it is stable under the conditions of CMP and does not adversely affect the process of the invention. Examples for suitable substituent are fluorine atoms, chlorine atoms or nitrile groups.

Preferably, the residue R of the general formulas I and II represents a hydrogen atom, a chlorine atom, a nitrile group or a methyl group, more preferably a hydrogen atom or a methyl group, most preferably a hydrogen atom.

The residues R¹ and R² of the general formula I can be the same or can be different from each other. They represent independently of each other hydrogen atoms or residues comprising or consisting at least one, preferably one, moiety selected from the group consisting of substituted and unsubstituted aliphatic moieties having 1 to 20 carbon atoms, substituted and unsubstituted cycloaliphatic moieties having 3 to 10 carbon atoms, substituted and unsubstituted aromatic moieties having 6 to 10 carbon atoms.

Preferably, the residues R¹ and R² of the general formula I are the same or different from each other and are independently of each other selected from the group consisting of hydrogen atoms, methyl, ethyl, propyl, isopropyl, cyclopentyl, cyclohexyl and phenyl groups and mixtures thereof, preferably hydrogen atoms and methyl groups. Most preferably, hydrogen atoms are used.

The residue R³ of the general formula II represents a substituted or unsubstituted, saturated heterocyclic ring containing at least one, preferably one, nitrogen atom, the said heterocyclic ring being linked to the carbon atom of the carbonyl moiety via a covalent carbon nitrogen bond.

Preferably, the residue R³ of the general formula II represents a morpholino, thiomorpholino, pyrrolidino or piperidino group.

Additional suitable acrylamide monomers of the general formula I and II are disclosed in the American patent application US 2007/0175104 A1, paragraphs [0041] to [0043] and

Most preferably, acrylamide is used as the acrylamide monomer.

The copolymers (c2) may contain monomeric units derived from customary and known olefinically unsaturated monomers other than the acrylamides of the general formula I and II, as for example, vinyl esters and ethers, acrylic and methacrylic esters, allylic esters and ethers, olefins which may be substituted by halogen atoms or nitrile groups, and styrenic monomers, provided that such monomeric units are only contained in such amounts that the water-solubility is not jeopardized.

The homopolymers and copolymers (c2) have a weight average molecular weight of less than 100,000 Dalton, preferably less than 75,000 Dalton, more preferably less than 50,000 Dalton and most preferably less than 20,000 Dalton. Most preferably, the lower limit of the weight average molecular weight is 5000 Dalton.

The polymer (c3) is a cationic polymeric flocculant.

Preferably, the cationic polymeric flocculant (c3) is selected from the group consisting of cationically modified polyacrylamides, polyamines, polyethyleneimines, poly(diallyl-N,N-dialkylammonium halides) and mixtures thereof.

More preferably, the cationic groups are selected from the group consisting of tertiary and quaternary ammonium groups, secondary sulfonium groups, tertiary phosphonium groups and mixtures thereof. Most preferably, quaternary ammonium groups are used.

More preferably, the alkyl group of the poly(diallyl-N,N-dialkylammonium halide) (c3) is selected from the group consisting of methyl, ethyl, propyl and isopropyl and mixtures thereof. Most preferably, methyl groups are used. More preferably, the halide is selected from the group consisting of fluoride, chloride and bromide. Most preferably, chloride is used. Most preferably, poly(diallyl-N,N-dimethylammonium chloride) (poly-DADMAC) is used.

The cationically modified flocculants (c3) are customary and known materials which are commercially available, as for example, from BASF SE under the trademark Sedipur™ C.,

The concentration of the water-soluble or water-dispersible polymer (C) in the polishing composition can vary broadly and, therefore, can be adjusted most advantageously to the particular requirements of a given composition and process of the invention. Preferably, the composition contains the polymer (C) in amounts of from 0.0001 to 5% by weight, more preferably 0.0005 to 2.5% by weight, even more preferably 0.00075 to 1% by weight and, most preferably, 0.00075 to 0.5% by weight, based on the complete weight of the polishing composition.

The polishing composition can contain at least one functional component (D) which is different from the ingredients or components (A), (B) and (C).

Preferably, the functional component (D) is selected from the group of compounds customarily used in ceria-based CMP slurries.

More preferably, the functional component (D) is selected from the group consisting of organic, inorganic and hybrid organic-inorganic abrasive particles being different from the particles (D), polyhydric alcohols having at least 2 hydroxide groups and oligomers and polymers thereof, hydroxycarboxylic acids and their esters and lactones, materials having a lower critical solution temperature LOST or an upper critical solution temperature UCST, oxidizing agents, passivating agents, charge reversal agents, complexing or chelating agents, frictive agents, stabilizing agents, rheology agents, surfactants, metal cations and organic solvents.

Suitable organic abrasive particles (D) and their effective amounts are known, for example, from the American patent application US 2008/0254628 A1, page 4, paragraph [0054] or from the international application WO 2005/014753 A1, wherein solid particles consisting of melamine and melamine derivatives such as acetoguanamine, benzoguanamine and dicyandiamide are disclosed.

Suitable inorganic abrasive particles (D) and their effective amounts are known, for example, from the international patent application WO 2005/014753 A1, page 12, lines 1 to 8 or the U.S. Pat. No. 6,068,787, column 6, line 41 to column 7, line 65.

Suitable hybrid organic-inorganic abrasive particles (D) and their effective amounts are known, for example, from the American patent applications US 2008/0254628 A1, page 4, paragraph [0054] or US 2009/0013609 A1, page 3, paragraph [0047] to page 6, paragraph [0087].

Suitable polyhydric alcohols (D) are diols such as ethylene glycol and propylene glycol, triols such as glycerol, pentaerythritol, alditols, cyclitols and dimers and oligomers of glycerol, trimethylolpropane, pentaerythritol, alditols and cyclitols.

Suitable hydroxycarboxylic acids (D) are in aldonic acids, uronic acids, glycuronic acids, aldaric acids, ulusonic acids, neuraminic acids and sialic acids and esters and lactones thereof.

Suitable oxidizing agents (D) and their effective amounts are known, for example, from the European patent application EP 1 036 836 A1, page 8, paragraphs [0074] and [0075] or from the U.S. Pat. No. 6,068,787, column 4, line 40 to column 7, line 45 or U.S. Pat. No. 7,300,601 B2, column 4, lines 18 to 34. Preferably, organic and inorganic peroxides, more preferably inorganic peroxides, are used. In particular, hydrogen peroxide is used.

Suitable passivating agents (D) and their effective amounts are known, for example, from the U.S. Pat. No. 7,300,601 B2, column 3, line 59 to column 4, line 9 or from the American patent application US 2008/0254628 A1, the paragraph [0058] bridging the pages 4 and 5.

Suitable complexing or chelating agents (D), which are sometimes also designated as frictive agents (cf. the American patent application US 2008/0254628 A1, page 5, paragraph [0061]) or etching agents or etchants (cf. the American patent application US 2008/0254628 A1, page 4, paragrap [0054]), and their effective amounts are known, for example, from the U.S. Pat. No. 7,300,601 B2, column 4, lines with 35 to 48. The amino acids, in particular glycine, and, moreover, dicyandiamide and triazines containing at least one, preferably two and, more preferably, three primary amino groups such as melamine and water-soluble guanamines, particularly melamine, formoguanamine, acetoguanamine and 2,4-diamino-6-ethyl-1,3,5-triazine, are most particularly preferably used.

Suitable stabilizing agents (D) and their effective amounts are known, for example, from the U.S. Pat. No. 6,068,787, column 8, lines 4 to 56.

Suitable rheology agents (D) and their effective amounts are known, for example, from the American patent application US 2008/0254628 A1, page 5, paragraph [0065] to page 6, paragraph [0069].

Suitable surfactants (D) and their effective amounts are known, for example, from the international patent application WO 2005/014753 A1, page 8, line 23, to page 10, line 17 or from the U.S. Pat. No. 7,300,601 B2, column 5, line 4 to column 6, line 8.

Suitable polyvalent metal ions (D) and their effective amounts are known, for example, from the European patent application EP 1 036 836 A1, page 8, paragraph [0076] to page 9, paragraph [0078].

Suitable organic solvents (D) and their effective amounts are known, for example, from the U.S. Pat. No. 7,361,603 B2, column 7, lines 32 to 48 or the American patent application US 2008/0254628 A1, page 5, paragraph [0059].

Suitable materials (D) exhibiting a lower critical solution temperature LOST or an upper critical solution temperature UCST are described, for example, in the article of H. Mori, H. lwaya, A. Nagai and T. Endo, Controlled synthesis of thermoresponsive polymers derived from L-proline via RAFT polymerization, in Chemical Communication, 2005, 4872-4874; or in the article of D. Schmaljohann, Thermo- and pH-responsive polymers and drug delivery, Advanced Drug Delivery Reviews, volume 58 (2006), 1655-1670 or in the American patent applications US 2002/0198328 A1, US 2004/0209095 A1, US 2004/0217009 A1, US 2006/0141254 A1, US 2007/0029198 A1, US 2007/0289875 A1, US 2008/0249210 A1, US 2008/0050435 A1 or US 2009/0013609 A1, the U.S. Pat. No. 5,057,560, U.S. Pat. No. 5,788,82 and U.S. Pat. No. 6,682,642 B2, the international patent applications WO 01/60926 A1, WO2004/029160 A1, WO 2004/0521946 A1, WO 2006/093242 A2 or WO 2007/012763 A1, in the European patent applications EP 0 583 814 A1, EP 1 197 587 B1 and EP 1 942 179 A1, or the German patent application DE 26 10 705.

In principle, any known charge reversal agent (D) customarily used in the field of CMP can be used. Preferably, the charge reversal agent (D) is selected from the group consisting of monomeric, oligomeric and polymeric compounds containing at least one anionic group selected from the group consisting of carboxylate, sulfonate, sulfate and phosphonate groups.

If present, the functional component (D) can be contained in varying amounts. Preferably, the total amount of (D) is not more than 10 wt. % (“wt. %” means “percent by weight”), more preferably not more than 2 wt. %, most preferably not more than 0.5 wt. %, particularly not more than 0.1 wt. %, for example not more than 0.01 wt. %, based on the total weight of the corresponding CMP composition. Preferably, the total amount of (D) is at least 0.0001 wt. %, more preferably at least 0.001 wt. %, most preferably at least 0.008 wt. %, particularly at least 0.05 wt. %, for example at least 0.3 wt. %, based on the total weight of the corresponding composition.

The composition used in the process of the invention can optionally contain at least one pH-adjusting agent or buffering agent (E) which is materially different from the ingredients (A), (B) and (C).

Suitable pH-adjusting agents or buffering agents (E) and their effective amounts are known, for example, from the European patent application EP 1 036 836 A1, page 8, paragraphs [0080], [0085] and [0086], the international patent application WO 2005/014753 A1, page 12, lines 19 to 24, the American patent application US 2008/0254628 A1, page 6, paragraph [0073] or the U.S. Pat. No. 7,300,601 B2, column 5, lines 33 to 63. Examples for pH-adjusting agents or buffering agents (E) are potassium hydroxide, ammonium hydroxide, tetramethylammonium hydroxide (TMAH), nitric acid, and sulfuric acid.

If present, the pH-adjusting agent or buffering agent (E) can be contained in varying amounts. Preferably, the total amount of (E) is not more than 20 wt. %, more preferably not more than 7 wt. %, most preferably not more than 2 wt. %, particularly not more than 0.5 wt. %, for example not more than 0.1 wt. %, based on the total weight of the corresponding CMP composition. Preferably, the total amount of (E) is at least 0.001 wt. %, more preferably at least 0.01 wt. %, most preferably at least 0.05 wt. %, particularly at least 0.1 wt. %, for example at least 0.5 wt. %, based on the total weight of the corresponding composition.

Preferably, the pH of the composition used in the process of the invention is set between 3 and 10, more preferably, 3 and 8, even more preferably between 3 and 7, and, most preferably between 5 and 7 preferably using the aforementioned pH-adjusting agents (E).

The preparation of the composition does not exhibit any particularities but can be carried out by dissolving or dispersing the above-described ingredients (A), (B) and (C) and optionally (D) and/or (E) in an aqueous medium, in particular, de-ionized water. For this purpose, the customary and standard mixing processes and mixing apparatuses such as agitated vessels, in-line dissolvers, high shear impellers, ultrasonic mixers, homogenizer nozzles or counterflow mixers, can be used. Preferably, the composition used in the process of the invention thus obtained can be filtered through filters of the appropriate mesh aperture, in order to remove coarse-grained particles such as the agglomerates or aggregates of the solid, finely dispersed abrasive particles (A).

The compositions are excellently suited for the process of the invention.

In the process of the invention, a substrate for electrical, mechanical and optical devices, in particular, electrical devices, most preferably, integrated circuit devices, is contacted at least once with the said composition and polished, in particular, chemically and mechanically polished, until the desired planarity is achieved and the polysilicon layer is exposed.

Therefore, the process on the invention exhibits its particular advantages in the CMP of silicon semiconductor wafers having isolating layers consisting of low-k or ultra-low-k silicon oxide materials and polysilicon layers, optionally containing silicon nitride layers.

Suitable low-k or ultra-low-k materials and suitable methods of preparing the insulating dielectric layers are described in, for example, the American patent applications US 2005/0176259 A1, page 2, paragraphs [0025] to [0027], US 2005/0014667 A1, page 1, paragraph [0003], US 2005/0266683 A1, page 1, paragraph [0003] and page 2, paragraph or US 2008/0280452 A1, paragraphs [0024] to [0026] or in the U.S. Pat. No. 7,250,391 B2, column 1, lines 49 to 54 or in the European patent application EP 1 306 415 A2, page 4, paragraph [0031].

The process of the invention is particularly suited for the shallow trench isolation (STI) which requires the selective removal of silicon dioxide over polysilicon on a patterned wafer substrate. In this process, etched trenches are overfilled with the dielectric material, e.g., silicon dioxide, which is polished using the polysilicon barrier film as the stopping layer. In this preferred embodiment, the process of the invention ends with clearing the silicon dioxide from the barrier film while minimizing the removal of exposed polysilicon and trench silicon oxide.

Moreover, the process of the invention is also particularly well-suited for the shallow trench isolation (STI) wherein a silicon nitride film or a silicon nitride and a polysilicon film is or are present, because the process of the invention exhibits a high nitride-to-polysilicon selectivity in conjunction with a moderate oxide-to-nitride selectivity.

Thus, the process of the invention exhibits an oxide-to-polysilicon selectivity greater than 50.

The process of the invention exhibits no particularities but can be carried out with the processes and the equipment customarily used for the CMP in the fabrication of semiconductor wafers with ICs.

As is known in the art, a typical equipment for the CMP consists of a rotating platen which is covered with a polishing pad. The wafer is mounted on a carrier or chuck with its upper side down facing the polishing pad. The carrier secures the wafer in the horizontal position. This particular arrangement of polishing and holding device is also known as the hard-platen design. The carrier may retain a carrier pad which lies between the retaining surface of the carrier and the surface of the wafer which is not being polished. This pad can operate as a cushion for the wafer.

Below the carrier, the larger diameter platen is also generally horizontally positioned and presents a surface parallel to that of the wafer to be polished. Its polishing pad contacts the wafer surface during the planarization process. During the CMP process of the invention, the composition used in the process of the invention is applied onto the polishing pad as a continuous stream or in dropwise fashion.

Both the carrier and the platen are caused to rotate around their respective shafts extending perpendicular from the carrier and the platen. The rotating carrier shaft may remain fixed in position relative to the rotating platen or may oscillate horizontally relative to the platen. The direction of rotation of the carrier typically, though not necessarily, is the same as that of the platen. The speeds of rotation for the carrier and the platen are generally, though not necessarily, set at different values.

Customarily, the temperature of the platen is set at temperatures between 10 and 70° C.

For further details reference is made to the international patent application WO 2004/063301 A1, in particular page 16, paragraph [0036] to page 18, paragraph [0040] in conjunction with the FIG. 1.

By way of the process of the invention semiconductor wafers with ICs comprising patterned polysilicon and low-k and ultra-low-k material layers, in particular silicon dioxide layers, having an excellent planarity can be obtained. Therefore, copper damascene patterns can be obtained which also have an excellent planarity and, in the finished, IC an excellent electrical functionality.

### Example 1 and Comparative Experiments C1 to C3

CMP of Polysilicon Coated, Silicon Nitride Coated and Silicon Dioxide Coated Blanket Wafers and Oxide-To-Polysilicon, Oxide-To-Nitride and Nitride-To-Polysilicon Selectivity

The aqueous polishing compositions 1 to 4 were prepared for the example 1 and the comparative experiments C1 to C3 respectively. To this end, ceria (average particle size d₅₀ of 120 to 140 Nm as determined by dynamic laser light scattering), polyethylene glycol (PEG_{10K}; weight average molecular weight: 10,000 Dalton), and polyacrylamide (PAL_{10K}; a weight average molecular weight: 10,000 Dalton) were dispersed or dissolved in ultrapure water. The amounts used are compiled in the Table 1.

TABLE 1
The Compositions of the Aqueous Polishing Compositions 1 to 4

| Composition | Ceria/% by | PEG_{10K}/% by | PAL_{10K}/% by | |
|---|---|---|---|---|
| No. | weight | weight | weight | pH |
| 1 (invention) | 0.5 | 0.25 | 0.25 | 5.1 |
| 2 (comparison) | 0.5 | — | — | 5.5 |
| 3 (comparison) | 0.5 | — | 0.25 | 5.1 |
| 4 (comparison) | 0.5 | 0.2 | — | 5.1 |

The composition No. 1 of Table 1 was used for the example 1. The compositions 1 to 3 of Table 1 were used for the comparative experiments C1 to C3 respectively.

The CMP process parameters were as follows:
Polishing apparatus: Strasbaugh 6EGnHance (rotary type):
platen speed: 71 rpm;
carrier speed: 70 rpm;
IC 1000/Suba 400 K-groove polishing pad manufactured by Rohm & Haas;
in situ conditioning using S60 3M diamond conditioner;
slurry flow rate: hundred and 50 ml/min;
substrates: 200 mm thermal oxide blanket wafers from SKW, polysilicon coated blanket wafers and silicon nitride coated blanket wafers;
down force: 2.5 psi (171.43 mbar);
polishing time: 1 minute.

The material removal rates MRRs were measured with a reflectometer. The obtained results are compiled in the Table 2.

TABLE 2
Thermal Oxide, Silicon Nitride and Polysilicon Removal Rates MRRs

| Example or | | | | Silicon |
|---|---|---|---|---|
| Comparative | | Thermal | Polysilicon | Nitride |
| Experiment | Composition | oxide MRR | MRR | MRR |
| No. | No. | (Å/min) | (Å/min) | (Å/min) |
| 1 | 1 | 1076 | 21 | 102 |
| C1 | 2 | 3947 | 415 | 629 |
| C2 | 3 | 1093 | 1013 | 145 |
| C3 | 4 | 3973 | 109 | 675 |

The calculated selectivities are compiled in the Table 3.

TABLE 3
The Oxide-To-Polysilicon, Oxide-To-Nitride and Nitride-To-Polysilicon
Selectivities

| Example or | | | | |
|---|---|---|---|---|
| Comparative | | Oxide-To- | Oxide-To- | Nitride-To- |
| Experiment | Composition | Polysilicon | Nitride | Polysilicon |
| No. | No. | Selectivity | Selectivity | Selectivity |
| 1 | 1 | 51 | 10.5 | 4.8 |
| C1 | 2 | 9.5 | 6.27 | 1.55 |
| C2 | 3 | 1 | 7.53 | 0.14 |
| C3 | 4 | 36 | 5.88 | 6.19 |

The results of Table 3 make apparent that there was an unexpected synergism between PEG_{10K} and PAL_{10K}: PAL_{10K} used alone had a detrimental effect on the oxide-to-polysilicon selectivity whereas the oxide-to-nitride selectivity was not an affected (cf. comparative experiment C2). PEG_{10K} used alone at least increased the oxide-to-polysilicon selectivity, which, however, remained below 50. Again, the oxide-to-nitride selectivity was not affected (cf. the comparative experiment C3). The significant increase of the selectivity achieved by the joint use of both polymers was therefore completely unexpected. The oxide-to-nitride selectivity was in the advantageous range which avoided dishing and other damages and defects in globally planarized, heterogeneous, patterned surfaces containing silicon dioxide, silicon nitride and polysilicon areas.

### Examples 2 to 11 and Comparative Experiments C4 and C5

CMP of Polysilicon Coated, Silicon Nitride Coated and Silicon Dioxide Coated Blanket Wafers and Oxide-To-Polysilicon, Oxide-To-Nitride and Nitride-To-Polysilicon Selectivity

The aqueous polishing compositions 2 to 13 were prepared for the examples 2 to 11 and the comparative experiments C4 and C5 respectively. To this end, ceria (average particle size d₅₀ of 120 to 140 Nm as determined by dynamic laser light scattering), polyethylene glycol (PEG_{10K}; weight average molecular weight: 10,000 Dalton), and a cationically modified polyacrylamide flocculant (Sedipur™ CL 520 of BASF SE) were dispersed or dissolved in ultrapure water. The pH of the aqueous polishing compositions 2 to 13 was adjusted to 5. The amounts used are compiled in the Table 4.

TABLE 4
The Compositions of the Aqueous Polishing Compositions 2 to 13

| | | | Sedipur ™ CL |
|---|---|---|---|
| Composition | Ceria/% by | PEG_{10K}/% by | 520/% by |
| No. | weight | weight | weight |
| 2 (invention) | 0.5 | 0.2 | 0.05 |
| 3 (invention) | 0.5 | 0.2 | 0.075 |
| 4 (invention) | 0.5 | 0.2 | 0.095 |
| 5 (invention) | 0.5 | 0.2 | 0.1 |
| 6 (invention) | 0.5 | 0.2 | 0.15 |
| 7 (invention) | 0.5 | 0.2 | 0.155 |
| 8 (invention) | 0.5 | 0.2 | 0.2 |
| 9 (invention) | 0.5 | 0.2 | 0.25 |
| 10 (invention) | 0.5 | 0.2 | 0.3 |
| 11 (invention) | 0.5 | 0.2 | 0.35 |
| 12 | 0.5 | — | — |
| (comparison) | | | |
| 13 | 0.5 | — | 0.155 |
| (comparison) | | | |

The compositions Nos. 2 to 11 of Table 3 were used for the examples 2 to 11. The compositions 12 and 13 of Table 4 were used for the comparative experiments C4 and C5 respectively.

The MRRs were determined as described in the example 1 and the comparative experiments C1 to C3, except that HDP silicon dioxide (high density plasma deposited silicon dioxide) blanket wafers were used instead of the thermal silicon dioxide blanket wafers.

The results are compiled in the Table 5.

TABLE 5
HDP Silicon Dioxide, Silicon Nitride and Polysilicon
Removal Rates MRRs

| Example or | | | Silicon | |
|---|---|---|---|---|
| Comparative | | HDP | Nitride | Polysilicon |
| Experiment | Composition | MRR | MRR | MRR |
| No. | No. | (Å/min) | (Å/min) | (Å/min) |
| 2 | 2 | 3470 | 862 | 31 |
| 3 | 3 | 2964 | 818 | 31 |
| 4 | 4 | 1964 | 896 | 44 |
| 5 | 5 | 532 | 912 | 48 |
| 6 | 6 | 206 | 962 | 37 |
| 7 | 7 | 259 | 980 | 62 |
| 8 | 8 | 87 | 954 | 23 |
| 9 | 9 | 66 | 906 | 27 |
| 10 | 10 | 31 | 735 | 18 |
| 11 | 11 | 41 | 176 | 17 |
| C4 | 12 | 3947 | 629 | 415 |
| C5 | 13 | 269 | 1055 | 1599 |

The calculated selectivities are compiled in the Table 6.

TABLE 6
The Oxide-To-Polysilicon, Oxide-To-Nitride and Nitride-To-Polysilicon
Selectivities

| Example or | | | | |
|---|---|---|---|---|
| Comparative | | Oxide-To- | Oxide-To- | Nitride-To- |
| Experiment | Composition | Polysilicon | Nitride | Polysilicon |
| No. | No. | Selectivity | Selectivity | Selectivity |
| 2 | 2 | 119.9 | 4 | 27.8 |
| 3 | 3 | 95.6 | 3.6 | 26.4 |
| 4 | 4 | 44.6 | 2.2 | 20.3 |
| 5 | 5 | 11.1 | 0.58 | 19 |
| 6 | 6 | 5.56 | 0.21 | 26 |
| 7 | 7 | 4.17 | 0.26 | 15.8 |
| 8 | 8 | 3.78 | 0.09 | 41.5 |
| 9 | 9 | 2.4 | 0.073 | 33.5 |
| 10 | 10 | 1.72 | 0.042 | 40.8 |
| 11 | 11 | 2.41 | 0.23 | 10.3 |
| C4 | 12 | 9.5 | 6.27 | 1.5 |
| C5 | 13 | 0.16 | 0.25 | 0.66 |

The results of the Table 6 make apparent that the polishing behavior of the compositions 2 to 11 of the examples 2 to 11 could be tailored in the most surprising way.

Sedipur™ CL 120 used alone significantly enhanced the silicon nitride and polysilicon MRR over the silicon dioxide MRR. Therefore, it acted as oxide suppressor and nitride and polysilicon enhancer (cf. the comparative experiments C4 and C5).

The compositions 2 to 11 containing Sedipur™ CL 120 in combination with PEG_{10K} exhibited a complex polishing behavior which depended on the concentration of the Sedipur™ CL 120.

At very low concentrations of Sedipur™ CL 120, the oxide-to-polysilicon selectivity was significantly increased, whereas the oxide-to-nitride selectivity remained in a moderate range below 10. In view of the fact that Sedipur™ CL 120 as such acted as an oxide suppressor and a nitride and polysilicon enhancer, this result was surprising (cf. the examples 2 to 4).

With increasing concentrations of Sedipur™ CL 120, the oxide-to-polysilicon selectivity decreased drastically. But still, silicon dioxide was more preferably polished than polysilicon, i.e., the selectivity was still >1. In contrast to this, the oxide-to-nitride selectivity sank below 1, i.e., silicon nitride was more preferably polished than silicon dioxide (cf. the examples 5 to 11). These effects were very pronounced. Surprisingly, the nitride-to-polysilicon selectivity remained high, i.e., >10 (cf. the examples 2 to 11).

Consequently, the polishing behavior of the compositions 2 to 11 could be most advantageously tailored in an easy way in order to solve problems associated with particular CMP processes.

1. A process for chemically mechanically polishing a substrate comprising a silicon oxide dielectric film and a polysilicon film, the process comprising:
contacting the substrate with an aqueous polishing composition,
polishing the substrate at a temperature and for a time sufficient to remove the silicon oxide dielectric film and expose a polysilicon nitride film, a silicon nitride film, or both, to obtain a polished substrate; and
removing the polished substrate from contact with the aqueous polishing composition.,
wherein the aqueous polishing composition comprises:
abrasive particles which are positively charged when dispersed in an aqueous medium having a pH of from 3 to 9 as evidenced by an electrophoretic mobility;
at least one water-soluble or water-dispersible polymer selected from the group consisting of a linear alkylene oxide homopolymer, a branched alkylene oxide homopolymer, a linear alkylene oxide copolymer, and a branched alkylene oxide copolymer; and
at least one water-soluble or water-dispersible polymer selected from the group consisting of a linear aliphatic poly(N-vinylamide) homopolymer, a branched aliphatic poly(N-vinylamide) homopolymer, a linear cycloaliphatic poly(N-vinylamide) homopolymer, a branched aliphatic poly(N-vinylamide) homopolymer, a linear aliphatic poly(N-vinylamide) copolymer, a branched aliphatic poly(N-vinylamide) copolymer, a linear cycloaliphatic poly(N-vinylamide) copolymer, a branched aliphatic poly(N-vinylamide) copolymer, a homopolymer of an acrylamide monomer, a copolymer of an acrylamide monomer, and a cationic polymeric flocculant,
wherein
the acrylamide has formula I:
H₂C═C(—R)—C(═O)—N(—R¹)(—R²) (I), or formula II:
H₂C═C(—R)—C(═O)—R³ (II),
R is a hydrogen atom, a fluorine atom, a chlorine atom, a nitrile group, or a residue comprising at least one moiety selected from the group consisting of a substituted aliphatic moiety comprising 1 to 6 carbon atoms, an unsubstituted aliphatic moiety comprising 1 to 6 carbon atoms, a substituted cycloaliphatic moiety comprising 3 to 10 carbon atoms, an unsubstituted cycloaliphatic moiety comprising 3 to 10 carbon atoms, a substituted aromatic moiety comprising 6 to 10 carbon atoms, and an unsubstituted aromatic moiety comprising 6 to 10 carbon atoms;
R¹ and R² are each independently a hydrogen atom or a residue comprising at least one moiety selected from the group consisting of a substituted alipahtic moiety comprising 1 to 20 carbon atoms, an unsubstituted aliphatic moiety comprising 1 to 20 carbon atoms, a substituted cycloaliphatic moiety comprising 3 to 10 carbon atoms, an unsubstituted cycloaliphatic moiety comprising 3 to 10 carbon atoms, a substituted aromatic moiety comprising 6 to 10 carbon atoms., and an unsubstituted aromatic moiety comprising 6 to 10 carbon atoms;
R³ is a substituted or unsubstituted, saturated heterocyclic ring comprising a nitrogen atom, wherein the heterocyclic ring is linked to a carbon atom of a carbonyl moiety via a covalent carbon nitrogen bond;
the homopolymers and copolymers have a weight average molecular weight of less than 100,000 Dalton; and
the cationic polymeric flocculant has a weight average molecular weight of less than 100,000 Dalton.

2. The process according to claim 1, wherein an oxide-to-polysilicon selectivity is >50.

3. The process according to claim 1, wherein the abrasive particles comprise ceria.

4. The process according to claim 1, wherein the linear and branched alkylene oxide homopolymers and copolymers are at least one selected from the group consisting of an ethyleneoxide homopolymer, a propyleneoxide homopolymer, an ethylene oxide copolymer, and a propyleneoxide copolymer.

5. The process according to claim 4, wherein the linear and branched alkylene oxide homopolymers and copolymers are polyethylene glycol.

6. The process according to claim 4, wherein the linear or branched, aliphatic or cycloaliphatic poly(N-vinylamide) homopolymers or copolymers are at least one selected from the group consisting of a homopolymer and copolymer of aliphatic and cycloaliphatic N-vinylamide monomers,
wherein the aliphatic and cycloaliphatic N-vinylamide monomers are at least one selected from the group consisting of N-vinylacetamide, N-vinylpyrrolidone, N-vinylvalerolactam, N-vinylcaprolactam, and N-vinylsuccinimide.

7. The process according to claim 1, wherein the residue R of formula I is a hydrogen atom, a chlorine atom, a nitrile group or a methyl group.

8. The process according to claim 1, wherein the residues R¹ and R² are each independently selected from the group consisting of a hydrogen atom, a methyl group, an ethyl group, a propyl group, an isopropyl group, a cyclopentyl group, and a cyclohexyl group.

9. The process according to claim 1, wherein the residue R³ of formula II is a morpholino, thiomorpholino, pyrrolidino or piperidino group.

10. The process according to claim 1, wherein the cationic polymeric flocculant is a polyacrylamide having a weighted average molecular weight of 5000 to 20,000 Dalton.

11. The process according to claim 1, wherein the cationic polymeric flocculant is at least one selected from the group consisting of a cationically modified polyacrylamide, a cationically modified polyamine, a cationically modified polyethyleneimine, and a cationically modified poly(diallyl-N,N-dialylammonium halide).

12. The process according to claim 1, wherein the aqueous polishing composition further comprises a functional component different from the abrasive particles and the water-soluble or water-dispersible polymers.

13. The process according to claim 12, wherein the functional component is at least one selected from the group consisting of an organic abrasive particle, an inorganic abrasive particle, a hybrid organic-inorganic abrasive particle, a polyhydric alcohol comprising at least 2 hydroxy groups and an oligomer and polymer thereof, a hydroxycarboxylic acid, a hydroxycarboxylic acid ester, a hydroxycarboxylic acid lactone, a material having a lower critical solution temperature LCST or an upper critical solution temperature UCST, an oxidizing agent, a passivating agent, a charge reversal agent, a complexing agent, a chelating agent, a fictive agent, a stabilizing agent, a rheology agent, a surfactant, a metal cation and an organic solvent.

14. The process according to claim 1, wherein the aqueous polishing composition comprises a pH-adjusting agent or buffering agent different from the abrasive particles and the water-soluble or water-dispersible polymers.

15. The process according to claim 1, wherein a pH value of the aqueous polishing composition is from 3 to 7.

16. The process according to claim 1, wherein the substrate for electrical, mechanical and optical devices is chemically mechanically polished.

17. The process according to claim 16, wherein
the electrical devices are integrated circuit devices, liquid crystal panels, organic electroluminescent panels, printed circuit boards, micro machines, DNA chips, micro plants and magnetic heads;
the mechanical devices are high precision mechanical devices; and
the optical devices are optical glasses, inorganic electro-conductive films, optical integrated circuits, optical switching elements, optical waveguides, optical monocrystals, solid laser monocrystals, sapphire substrates for blue laser LEDs, semiconductor monocrystals, and glass substrates for magnetic disks.

18. The process according to claim 17, wherein the integrated circuit devices comprise integrated circuits with large-scale integration or very-large-scale integration, and have structures with dimensions below 50 nm.

19. The process according to claim 17, wherein
the optical glasses are photo masks, lenses, or prisms,
the inorganic electro-conductive films are indium tin oxide (ITO), and
the optical monocrystals are the end faces of optical fibers or scintillators.

20. The process according to claim 1, wherein a pH value of the aqueous polishing composition is from 5 to 7.
